(19) United States
(12) Patent Application Publication
(10) Pub. No.: US 2025/0208360 A1
(43) Pub. Date: Jun. 26, 2025

(54) SYSTEM AND APPARATUS FOR OPTICAL COUPLING

(71) Applicant: Samba Photonics Lab Inc, Irvine, CA (US)

(72) Inventors: Xiaolin Tong, Irvine, CA (US); Xiaotian Steve Yao, Las Vegas, NV (US); Danshu Rao, Beijing (CN)

(21) Appl. No.: 18/788,790

(22) Filed: Jul. 30, 2024

Related U.S. Application Data
(60) Provisional application No. 63/614,529, filed on Dec. 23, 2023.

(51) Int. Cl. G02B 6/42; H01S 5/02253; H01S 5/183

(52) U.S. Cl. CPC G02B 6/4206; H01S 5/02253; H01S 5/183

(57) ABSTRACT

A coupling system using micro-ellipsoid lens is disclosed. The system includes an array of the micro-ellipsoid lenses for coupling optical signals between silicon photonics devices and optical fibers. Preliminary micro-ellipsoid lenses are cut near the foci of the ellipsoid. The optical signals emanate from one focus and are reflected by the boundary of the ellipsoid. The reflective properties of the ellipsoid guarantees that the optical signals will pass through the other focus after the reflection. The optical signals are coupled to either the silicon photonics device or the optical fiber placed at the other focus.

### CROSS REFERENCE TO RELATED APPLICATIONS

This application claims the benefit under 35 U.S.C. § 119 (e) to U.S. Provisional Application Ser. No. 63/614,529 filed on Dec. 23, 2023. The entire contents of U.S. Provisional Application Ser. No. 63/614,529 are hereby incorporated herein by reference as if set forth in its entirety herein.

### BACKGROUND

The demand for high-speed data transmission has significantly increased with the advancement of digital communication technologies. Traditional electrical interconnects face limitations in bandwidth and distance due to problem such as signal attenuation and electromagnetic interference. Optical interconnects offer a solution to these limitations by providing higher bandwidth and longer transmission distances with minimal signal loss.

While optical interconnects are already central to telecommunication networks, such as in submarine networks, core network, and metro networks, they have not yet achieved the cost efficiency needed to replace electrical interconnects in short link applications. For instance, optical interconnects utilizing vertical cavity surface emitting lasers (VCSELs) are still much more expensive than their electrical counterparts.

Progress in integrating photonic functions into silicon substrates has been made to leverage the infrastructure and expertise used in the semiconductor fabrication of electronic integrated circuits, which has significantly reduced the costs associated with the optical interconnects. Silicon Photonics systems have been developed to address those needs.

In the realm of Silicon Phonics (SiPho), VCSELs are commonly used to convert electrical signals into optical signals and emit light that carries the data through an optical fiber or free space. Photodiodes (PD) are used for receiving optical signals-they detect the optical signal and convert it back into an electrical signal for processing.

Coupling optical signals between silicon photonics components and optical fibers can be challenging due to the many reasons, such as the differences in mode size and alignment requirements. The prior-art SiPho optical coupling systems suffer the following drawbacks:

1. Low Coupling Efficiency. Existing systems typically coupling efficiency is about 45% to max of 85%. Although serviceable, this level of efficiency is far from ideal, particularly in high-performance applications where such inefficiency significantly impacts overall system performance.

2. Physical Interfaces and Reflective Losses. The number of physical interfaces in current technologies is excessive, and reflective surfaces at these interfaces introduce higher optical losses. These reflections not only reduce the amount of light reaching the fiber but can also cause signal quality issues, such as optical polarization and optical noises.

3. Complexity in Design and Alignment Difficulty. Due to complex designs, optically aligning VCSELs with fibers becomes challenging, requiring precise adjustments to achieve optimal coupling. This not only increases the time cost of system setup but also raises the technical requirements for production and maintenance.

4. Time Consumption in the Coupling Process. Existing coupling techniques require substantial time for alignment and adjustment during operation, leading to inefficiency. In production and testing phases, this time consumption becomes a significant cost factor.

### BRIEF SUMMARY OF THE INVENTION

The present application proposes a lens coupling system designed to overcome the limitations of existing technology, enhance coupling efficiency, simplify the alignment process, and significantly reduce optical losses and interface related noises. Free from material selection, this new lens system optimizes coupling geometry, minimizes the number of optical interfaces in causing the performance impairment, providing higher coupling efficiency and reduced operational related complexity.

To overcome the problems described above, preferred embodiment of the present application provides a ball-lens optical coupling system (interchangeably hereinafter “ball-lens coupling system”, “optical coupling system”, “coupling system”) that includes one or more of the following:

An optical coupling system characterized by its configuration that reduces reflective surfaces.

An optical coupling system using optical total internal reflection instead of a “mirror, metal-surface” reflection mechanism.

An optical coupling system with dynamic numerical aperture to suppress the unwanted high-order mode, to improve and guide few-mode or single mode.

An optical coupling system capable of change the VCSEL or silicon slab grating emitted light to horizontal oriented fiber array.

An optical coupling system adapted for from multimode (“MM”) to MM, MM to a few modes, or single mode by properly design the ball-lens curvatures.

An optical coupling system equipped with mechanisms for precise control over light spot size and shape to optimize coupling into specific fiber types.

An optical coupling system where the TX and RX light patch symmetry and laser array pitch can be design with the flexible geometry.

An optical coupling system where reduced optical antireflective coating only needs to be applied on one surface that close to the VCSEL or the TX of the chip, with fiber-to-lens contact using epoxy and index-matching GEL to reduce the boundary effects.

An optical coupling system where the ball-lens geometry and optical index are adjustable to match various VCSEL and silicon slab grating configurations.

An optical coupling system featuring a detachable design that allows for easy removal and replacement of the ball-lens and other optical components to facilitate maintenance, upgrades, and/or customization.

The preferred embodiments of the present application also provide an optical coupling system with micro-ellipsoid lens that includes an array of the micro-ellipsoid lenses. Each micro-ellipsoid lens has an ellipsoid shape and includes a first focus and a second focus. Each micro-ellipsoid lens includes a first cut near or at the first focus and a second cut near or at second focus.

The optical coupling system further includes silicon photonics chip having a vertical cavity surface emitting lasers (VCSEL) or a photodiode (PD). The VCSEL emits transmission (Tx) optical signals and the PD receives reception (Rx) optical signals, and the silicon photonics chip is placed near the first focus.

The optical coupling system further includes an array of optical fibers placed near the second focus. The Tx optical signals are emitted from the VCSEL and received by the optical fiber array and the Rx optical signals are emitted from the optical fiber array and received by at least one PD.

In the optical coupling system, the Rx and Tx optical signals are totally reflected at a spot on a boundary of the micro-ellipsoid lens. The boundary of the micro-ellipsoid lens is an intact portion of the micro-ellipsoid lens.

In the optical coupling system of the Tx optical signal matches the mode of the optical fiber, and the Rx optical signal matches the mode of the PD.

In the optical coupling system, the array of the micro-ellipsoid lens includes a plurality of the micro-ellipsoid lens made from preliminary micro-ellipsoid lens. Each preliminary micro-ellipsoid lens is cut on a first side and a second side. The first side and the second side are identical and are located on opposing sides of the micro-ellipsoid lens. The plurality of the micro-ellipsoid lenses is bonded to each other on the first sides and the second sides to form the array.

In the optical coupling system plurality of micro-ellipsoid lenses are aligned using parallel light to ensure at least one of a focal area tolerance, pitch tolerance and spot size tolerance.

In the optical coupling system, the first cut and the second cut are made on each of the micro-ellipsoid lenses after bonding. In the optical coupling system, it may be that only one of a Tx optical signals and Rx optical signals are transported. In the coupling system, the micro-ellipsoid lenses have near ellipsoid shapes.

The optical coupling system further includes a modulator for the Tx optical signals or demodulator for the Rx optical signals; a multiplexer for the Tx optical signals or de-multiplexer for the Rx optical signals; and a bridge for the Tx optical signals or de-bridge for the Rx optical signals.

The present application further provides an optical coupler includes a fiber holder part holding an array of optical fibers, a lens part comprising an array of the micro-ellipsoid lenses, wherein ach micro-ellipsoid lens having an ellipsoid shape and comprising a first focus and a second focus, and wherein each micro-ellipsoid lens comprises a first cut near or at the first focus and a second cut near or at second focus.

The optical coupler further includes a PCB board comprising at least one of a vertical cavity surface emitting lasers (VCSEL) and a photodiode (PD), said VCSEL emits transmission (Tx) optical signals and said PD receives reception (Rx) optical signals, said silicon photonics chip is placed near the first focus.

The optical coupler further includes an array of optical fibers placed near the second focus. The Tx optical signals are emitted from the VCSEL and received by the optical fiber array and the Rx optical signals are emitted from the optical fiber array and received by at least one PD.

The optical coupler has other similar features described above in connection with the optical coupling system above and are incorporated herein by reference.

### BRIEF DESCRIPTION OF THE DRAWINGS

FIG. 1 illustrates an optical signal transmission system according to an example of the present application.

FIG. 2 illustrates a micro-ball lens array of a fiber array in the optical communication system according to an example of the present application.

FIG. 3 illustrates the light path of optical beam in the cut micro-ball lens on the Rx and Tx optical path according to an example of the present application

FIGS. 4A and 4B illustrate a micro-ellipsoid lens in a Tx optical path according to an example of the present application.

FIG. 5 illustrate an optical coupler using the micro-ellipsoid lens according to an example present application.

### DETAILED DESCRIPTION OF THE INVENTION

The following detailed description of the present application refers to the accompanying drawings, which form a part hereof and show, by way of illustration, specific embodiments in which the present application may be practiced. These embodiments are described in sufficient detail to enable those skilled in the art to practice the present application, and it is to be understood that other embodiments may be utilized and that structural changes may be made without departing from the scope of the present application.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

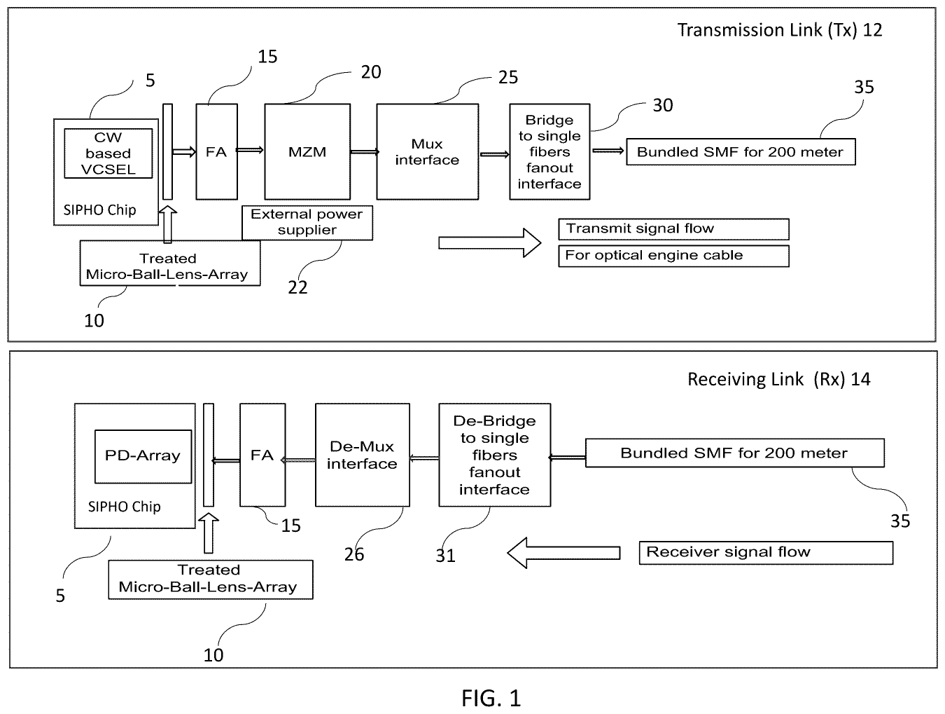

FIG. 1 is an optical signal transmission system according to preferred embodiments of the present application. SiPho chip 5 transmits and receives electrical signals, to electrical devices and systems outside of the SiPho chip 5. The electrical devices and systems are that located to the left-hand side of the SiPho chip 5 are not illustrated therein. The SiPho chip 5 transmits and receives optical signals via the optical coupler array 10. According to one example, the optical coupler array 10 includes an array of micro-ball lenses that couples the optical signals between the Sipho chip 5 and the fiber array 15. The micro-ball lenses are micro lenses having a ball shape and are described in further detail below. According to other examples of the present application, the lenses may be ellipsoid or spheroid, which are described in further details below. The shape of the lenses may be either a ball, an ellipsoid, a spheroid, or other shapes regular or irregular. The geometrical and mathematical definition of any shapes in connection with the optical coupler array 10 used throughout do not limit the scope of the application.

The optical paths of the optical signals include a transmission (Tx) link 12 and a reception (Rx) link 14. The direction of the Tx link 12 and Rx 14 are as indicated by right and left arrows in FIG. 1.

On the Tx link, the Tx signal goes through a variety of Tx link components. According to one example of the present application, SiPho chip 5 sends Tx link optical signals on the Tx link 12 emitted from the VCSEL, using technologies such as a continuous wave VCSEL. The optical couplers 10 couple the Tx optical signal to the fiber array (FA) 15 on the Tx link. The FA 15 may include any number of fibers. According to one example, the FA 15 is a ribbon array. Each fiber in FA 15 represents an optical channel on the Tx or Rx link, where the optical signal on that channel is transmitted or received between the SiPho chip 5 and the bundled optical fibers 35.

According to an example of the present application, the Tx link optical signals may be modulated, such as by an externally powered Mach-Zehnder modulator (MZM) 20. According to one example, the MZM modulator 20 is powered by an external power supply 22. The modulated Tx signal may be multiplexed by a multiplex interface 25. The multiplexed signal may be bridged to a single fiber fanout interface 30. Optical fibers 35 connected to the interface transport the optical signals out. According to one example illustrated in FIG. 1, the optical fibers are bundled single-mode optical fibers that transport the Tx link optical signals to up to 200 meters. According to other examples, the optical fibers 35 may be multi-mode fibers, hollow core fibers, hybrid fibers or any other fibers.

On the Rx link 14, the Rx signals are transported by optical fibers 35 to the optical coupling system in the reverse direction of the Tx link described above. According to the present application, the optical fibers 35 may be bundled single-mode fibers, multi-mode fibers, hollow core fibers or any other type of optical fibers that may be configured to transport the Rx optical signals to be processed to the SiPho chip 5.

Referring to FIG. 1, the Rx signal may be de-bridged to the single fiber fanout interface 31 on the Rx link 14. According to one example, the de-bridged Rx signals are de-multiplexed by de-multiplexer at the De-mux interface 26. The de-multiplexed Rx signal is mapped to the fiber array FA 15, with each fiber corresponds to an optical channel. In each channel, the Rx optical signal transported by the FA 15 is coupled to the PD on the SiPho chip 15 by optical coupler 10. The SiPho chip 15 converts the optical signals to electrical signals to be processed by the electrical system.

It is well-known in the art that optical fibers generally include a fiber core and cladding. Optical fibers vary in the size of their fiber cores. Single-mode fiber typically has a mode field diameter (MFD) around 8-10 micrometers (μm). Multi-mode fiber has a MFD around 50-62.5 μm. For optical fibers, the MFD differences are also reflected in the different numerical apertures (NA) of the fibers. Typically, the NA of single-mode fibers are around 0.10 to 0.15 and the NA of multi-mode fibers are around 0.20-0.30. Other types of fibers' NA also vary. The typical cross-sectional beam size (spot size) of the VCSEL varies around 3-10 μm. Mode matching, which ensures that the optical mode fields of different components in a system overlap, is critical in optical coupling. Good mode matching is essential to minimize coupling losses. If the mode fields are not well-matched, significant losses can occur due to the mismatch in the spatial distribution of the optical power. The coupling system of the present invention provides optimal mode-matching for fibers with any NA.

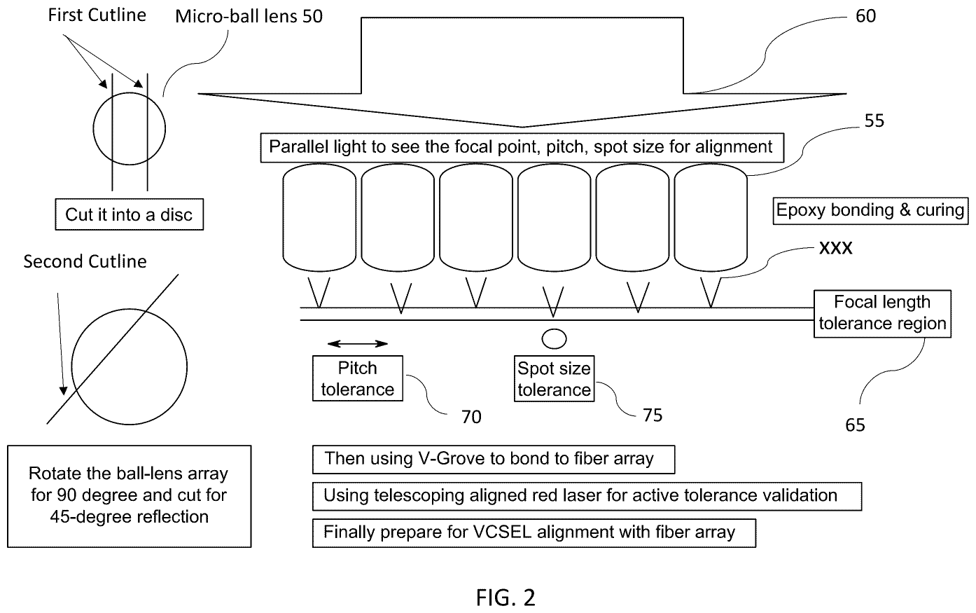

FIG. 2 illustrates a micro-ball lens array of a fiber array in the optical communication system according to a preferred embodiment of the present application. As explained above in connection with FIG. 1, although a ball-lens is described in FIG. 1, the lens can be the shape of any one of a ball, an ellipsoid, a spheroid or any other shape that do not conform to strict geometrical or mathematical definitions.

Referring to FIG. 2, a two-dimension (2D) projection of a preliminary single micro-ball lens 50 is illustrated therein. For simplicity, the ellipsoid is a ball in FIG. 2. Micro-ball lens and micro-ellipsoid lens are used interchangeably hereinafter throughout this application, wherein micro-ball includes micro-ellipsoid unless the context makes it clear that a micro-ball is not intended for the example. Further, when referring to a preliminary micro-ball or micro-ellipsoid lens in the application, it means a micro-ball or micro-ellipsoid lenses that are not cut or otherwise processed. The preliminary micro-ball or micro-ellipsoid has intact ball or ellipsoid shapes and cannot function as coupling lenses without further processing. According to the present application, the preliminary micro-ball or micro-ellipsoid lenses are manufactured and latently made into functioning coupling lenses based on the optical coupling design and need of a particular optical system. The processing may include multiple cutting at various orientations and select locations on the preliminary lenses, and further include bonding, curing, coating etc. to customize to the need of the optical coupling system. Those processed micro-ball or micro-ellipsoid lens micro-ball or micro-ellipsoid lens without further limitation, except when the context makes clear that it was not the intention therein.

Assume the preliminary micro-ball is in an XYZ Space, where the X-axis represents the horizontal dimension, Y-axis represents the vertical dimension and Z-axis represent the depth dimension. The micro-ball 50 is a 2D projection of the micro-ball on the X-Y plane. As shown in FIG. 2, the preliminary micro-ball lens is first cut on both sides along the cutlines, which forms a disc shape on the X-Y plane as illustrated therein. According to one example, the first cuts on the micro-ball are symmetrical. After the cut, the sides are discarded. The central disc-shape lenses are kept and later bonded on the sides to form a lens array 55 as illustrated in FIG. 2. To keep the lenses aligned, parallel light 60 may be used to ensure that the focal point is within the focal length tolerance region 65, the pitch is within the pitch tolerance range 70 between adjacent lenses, and the spot size is within the spot tolerance 75. According to an example, after the checking process, the optical fibers are placed on V-grooves for precise alignment and bonding. In the toleration validation process described above, telescoping aligned red lasers may be used.

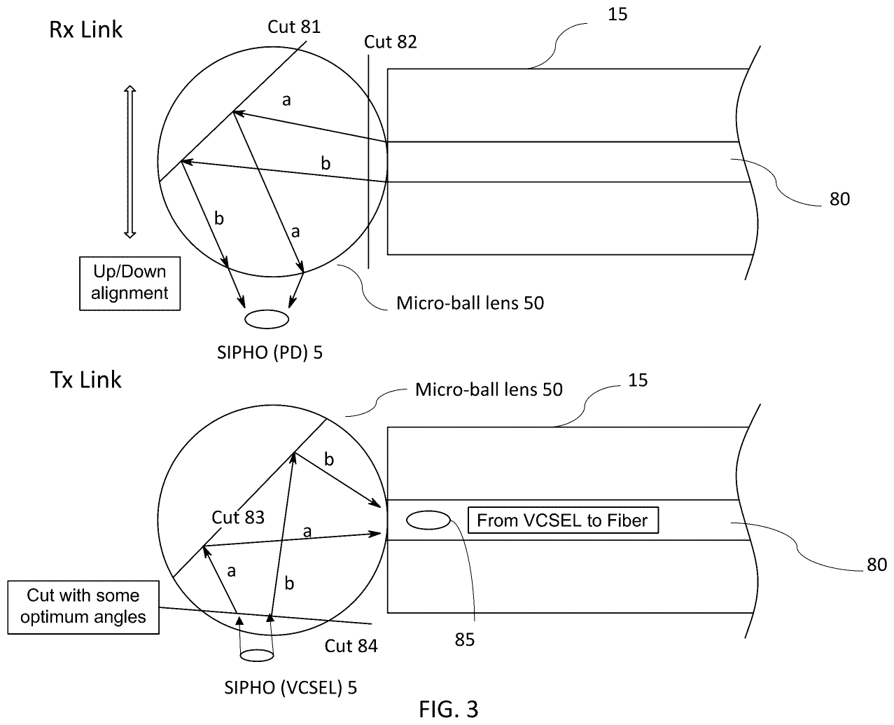

After the alignment with the optical fibers, the lenses are prepared for VCSEL alignment with fiber array. As illustrated in FIG. 2, a second cutline may be made on the micro-ball lens by rotating the lens array 90 degrees and cut the each of the rotated micro-ball lens in an angle such as 45 degrees. The second cutline can be seen on the X-Z plane. This cut and its effect on the optical path will be described in detail below in connection with the light path of the optical signals in connection with FIG. 3

FIG. 3 illustrates the light path of optical beam in the cut micro-ball lens on the Rx and Tx optical path. The Rx link is illustrated in the top half of FIG. 3 and the Tx link is illustrated in the bottom half of FIG. 3. Referring to FIG. 3 Rx link, the micro-ball lens 50 is coupled to the optical fiber 15. Two representative light paths a and b are illustrated therein. Those light paths are on the edge of the fiber core 80, where the optical beam is transported. Therefore, light paths a and b represent the boundaries of the optical beam transported by the fiber core 80.

As illustrated there, the Rx link micro-ball lens 50 receives the optical beam between light path a and light path b, reflects the light paths at cut 81, which change its direction from horizontal to vertical. After the reflection, the light beam continues to travel in the micro-ball lens and exits at the bottom of the lens into free space. Due to the lower refractive index of free space comparing to the micro-ball lens, the light beam quickly focuses after it exits the lens. The VCSEL chip 5 is located at a suitable distance where the spot size of the beam matches the mode of the PD for optimal optical coupling. On the vertical fiber-to-lens coupling end, another cut 82 may be made on the micro-ball lens. The cut 82 enhances the stability of the coupling between the optical fiber and the micro-ball lens. More importantly, it provides room for up-down alignment where the light path of the incoming optical beam may be adjusted for optimal coupling with the PD.

On the Tx optical path illustrated in the bottom half of FIG. 3, the micro-ball lens has a cut 84 at the bottom of the lens, where the optical beam emitted from VCSEL couples into the micro-ball lens 50 is received. The VCSEL beams are usually emitted and transmitted in an expanding cone shape, the spot size of the beam increasing at it propagates along the optical path. According to the example illustrated in FIG. 3, the cut 84 may tip a small angle in relation to the horizontal plane, which optimize the overall optical path of the

Tx beam for coupling to the optical fiber. The Tx optical path reflects at the reflective cut surface 83. Although both work to change the direction of the optical beam, the position and angle of the Tx optical path cut 83 may be different from the cut 81 on the Rx optical path. The initially expanding cone shape Tx beam starts focusing after the reflection cut surface 83. The cut surfaces 81 and 83 together with other elements of the optical path are determined in such a way that when the Tx optical beam reaches the exiting point of the micro-ball lens, its spot size 85 matches the size of the optical core 80 of fiber 15.

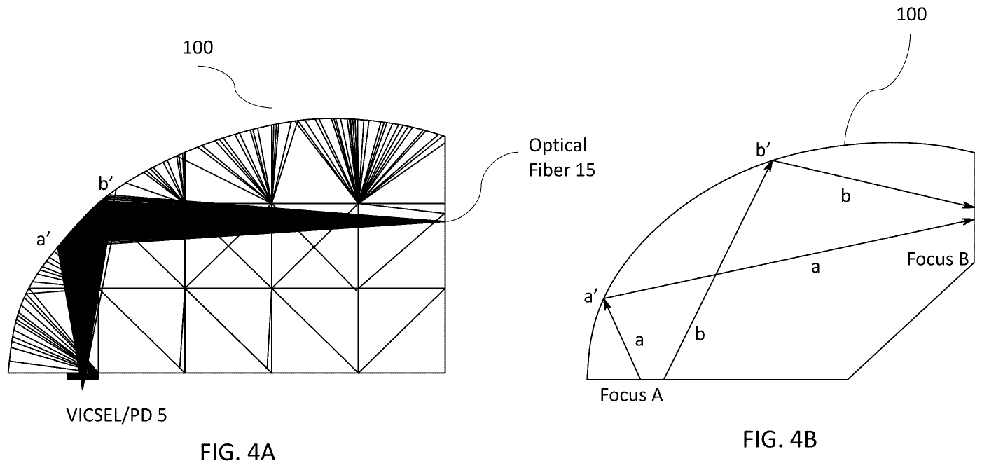

FIGS. 4A and 4B illustrate a micro-ellipsoid lens 100 in a Tx optical path according to an example of the present application. FIG. 4A illustrates a simulation of the micro-ellipsoid lens in 2D. FIG. 4B illustrates the light paths of the simulation in FIG. 4A. Referring to FIG. 4B, the micro-ellipsoid lens 100 is cut from a preliminary micro-ellipsoid lens (not shown). Tx light path in a two-dimensional projection of a cut micro-ellipsoid lens is illustrated therein. The two-dimensional projection of a micro-ellipsoid lens is part of an ellipse having two foci A and B. The micro-ellipsoid lens does not have a flat reflective cut similar to cuts 81 and 83 in FIG. 3. Instead, the light paths are reflected by the boundary of the micro-ellipsoid lens 100. Micro-ellipsoid lens 100 is cut near or across its focus A and focus B as illustrated therein. The optical beam emitted from the VCSEL enters the micro-ellipsoid lens 100 at focus A. Two light paths, a and b, representing the upper and lower boundary of the optical beam hit the boundary of the micro-ellipsoid lens 100 and reflects therefrom at a′ and b′ (hereinafter “reflection area”).

Total reflection occurs at the reflection area because the material of the micro-ellipsoid lens is so selected that it has a higher refractive index than outside of the lens, such as a glass micro-ellipsoid lens used in air. According to the reflective properties of the ellipses, a ray emanating from one focus reflects off the boundary of the ellipse and passes through the other focus. As such, all light paths that emanate from focus A and are reflected by the boundary will go through focus B.

FIG. 4A is a simulation of many light paths that are described above in connection with FIG. 4B. Referring to FIG. 4B, dense light rays emanate from the VCSEL/PD on the SiPho chip 5, which is placed on one fucus of the cut micro-ellipsoid lens. All light rays hit and are reflected by the boundary between the reflection area on the lens between a′ and b′. As demonstrated by the simulation, all reflected rays between a′ and b′ converge to one point, which is the other focus. An optical fiber 15 is placed at the focus to couple the light rays.

According to an example of the present application, the spot size of the exiting optical beam matches the mode of the optical fiber. According to an example of the present application, the point where the VCSEL beam enters the lens has a slight set-off from the focus A of the ellipse. According to an example of the present application, a coating is applied at the reflection area to enhance total reflection of the optical beam. According to an example of the present application, the curve on the boundary of the ellipse at the reflection area is further shaped such as by cutting, grating or other techniques where the area is not strictly part of an ellipse. According to an example of the present application, the micro lens is a three-dimensional body that resembles an ellipsoid but does not follow the mathematical definition of an ellipsoid, e.g. the radii of the ellipsoid may not be uniform, or that the outside curvature may not be smooth.

As illustrated in FIGS. 4A and 4B, the reflection area may be minimalized by adjusting the entry spot size of the VCSEL beam, the angle by which the optical beam enters the micro-ellipsoid lens, and the ratio of the radii of the ellipsoid etc. Further it can be appreciated that the reflection is achieved by total reflection based on the differences between refractive indices of the lens and air, which eliminate the need for using a mirror or inserting any metal surface reflection. The micro-spherical lens also features dynamic numerical aperture which may help suppress unwanted higher-order modes, to improve and guide few-mode or single mode.

The micro-ellipsoid lens for the Rx link is identical to the Tx link lens according to one example of the present application. According to another example, the Rx link lens is different from the Tx micro-ellipsoid lens. The main difference is in that the optical signals emanated from the fiber 15 and received by PD on the SiPho chip 5. Due to the reversibility of light paths, the optical signals emanated from one focus near optical fiber 15 hit and are reflected at the same reflection area. The optical signals all exit the Tx micro-ellipsoid lens at the other focus where the PD is placed. For lens used in the Rx link, it may differ in some aspect from the Tx lens. The Rx lens may have different ellipsoid parameters to adjust for the differences between the Tx link and the Rx link. One advantage of the present application is that differences between the Rx and Tx links can be accounted for in the design with minimal changes at low cost. While the Tx link couples optical beams of the input spot size of the VCSEL and the output spot size suitable for single-mode or multi-mode optical fiber cores, the Rx link takes optical beams with size of the optical fiber core and supplies the optical beams with a size that can be optimally coupled to the SiPho system, such as through PD. Those difference can be accommodated by finely adjusting the parameters, curvature, orientations and optical characteristics of the ellipsoid balls and the materials, coating and location in space of the coupling system. Such adjustments can be archived with low cost because the uniformly pre-manufactured preliminary lens can be adapted to different requirements of the optical links.

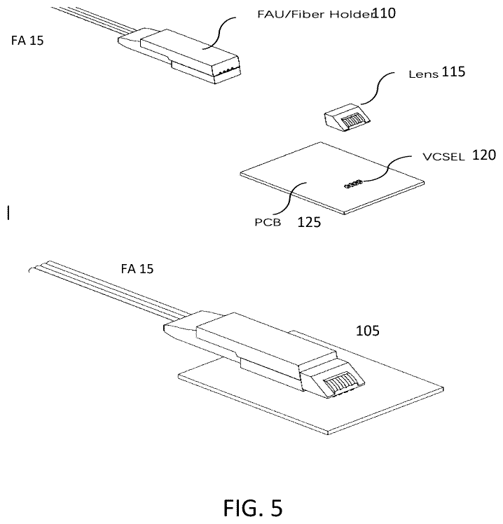

FIG. 5 illustrate an optical coupler using the micro-ellipsoid lens according to an example of the present application. The top part of FIG. 5 illustrates an explosive view of the coupler 105 and the bottom part illustrates an assembled view of the optical coupler 105 mounted on a PCB of a SiPho system. The coupler 105 includes the components of a FAU/fiber holder 110, a lens 115 and VCSEL 120. When assembled, they are mounted on a PCB board 125. The fiber array FA 15 has one end enclosed in the holder 110. The PCB board 125 may include mechanisms that allows it to be inserted into a connector (not shown). The connector can be included in an IC package, a host PCB or an interposer.

According to an example of the present application, each fiber of the fiber array 15 may be placed on a V-groove and inserted into a corresponding hole. The optical fibers are terminated and polished at the edge of the holder where the micro-ball or micro-ellipsoid lens will be placed. The lens includes an array of micro-ellipsoid lens 100, each corresponding to an optical fiber in the FA 15. The optical fibers may be permanently fixed in the holder 110 using suitable adhesive. While the optical fiber array depicted in FIG. 5 include four channels, any suitable number of optical fibers can be used, such as two, six, eight, twelve, and so on. Each optical fiber forms an individual optical channel. Increasing the number of optical fibers in the array enhances the total bandwidth and bandwidth density.

One advantage of the coupling system of the present application is that the optical beam only requires one total internal reflection of the optical beam to make the vertical-to-horizontal turn, and vice versa. This minimizes the number of reflections and the reflective surfaces, which reduces optical losses significantly.

Another advantage of the coupling system of the present application is that the lens geometry and optical index is adjustable, allowing customization to match different VCSEL and fiber configurations, including such as single-mode, multi-mode or hole-assisted fibers. By selecting different size, radii, curvature, material etc. of the micro-ellipsoid lens in the coupling system may meet wide ranges of customization needs at a low cost.

The coupling system includes a mechanism for dynamic adjustment of the optical numerical aperture. It helps in reducing undesirable higher-order modes and help enhance the propagation of desirable modes, whether it is few-mode or single-mode.

Although specific embodiments have been illustrated and described herein, it will be appreciated by those of ordinary skill in the art that a variety of alternate and/or equivalent implementations can be substituted for the specific embodiments shown and described without departing from the scope of the present disclosure. The embodiments described are not intended to be exhaustive or to limit the present application to the precise forms disclosed. Rather, they are chosen and described to best explain the principles of the present application and its practical applications, thereby enabling others skilled in the art to utilize the present application in various embodiments and with various modifications as are suited to the particular use contemplated. This application is intended to cover any adaptations or variations of the specific embodiments discussed herein. Therefore, it is intended that this disclosure be limited only by the claims and the equivalents thereof, and not by the specific examples given. The scope of the present application is to be determined by the claims appended hereto, interpreted in accordance with established doctrines of claim interpretation.

What is claimed is:

1. An optical coupling system with micro-ellipsoid lens, comprising:
An array of the micro-ellipsoid lenses, wherein each micro-ellipsoid lens having an ellipsoid shape and comprising a first focus and a second focus, and wherein each micro-ellipsoid lens comprises a first cut near or at the first focus and a second cut near or at second focus;
a silicon photonics chip comprising at least one of a vertical cavity surface emitting lasers (VCSEL) and a photodiode (PD), said VCSEL emits transmission (Tx) optical signals and said PD receives reception (Rx) optical signals, said silicon photonics chip is placed near the first focus;
an array of optical fibers placed near the second focus;
wherein the Tx optical signals are emitted from the VCSEL and received by the optical fiber array, and
wherein the Rx optical signals are emitted from the optical fiber array and received by at least one PD.

2. The optical coupling system of claim 1, wherein the Rx and Tx optical signals are totally reflected at a spot on a boundary of the micro-ellipsoid lens.

3. The optical coupling system of claim 2, wherein the boundary of the micro-ellipsoid lens is an intact portion of the micro-ellipsoid lens.

4. The optical coupling system of claim 1, wherein the Tx optical signal matches the mode of the optical fiber, and the Rx optical signal matches the mode of the PD.

5. The optical coupling system of claim 1, where in the array of the micro-ellipsoid lens of comprising:
a plurality of the micro-ellipsoid lens made from preliminary micro-ellipsoid lens which each preliminary micro-ellipsoid lens is cut on a first side and a second side;
wherein the first side and the second side are identical and are located on opposing sides of the micro-ellipsoid lens; and
wherein the cut plurality of the micro-ellipsoid lenses is bonded to each other on the first sides and the second sides to form the array.

6. The optical coupling system of claim 5, wherein the plurality of micro-ellipsoid lenses are aligned using parallel light to ensure at least one of a focal area tolerance, pitch tolerance and spot size tolerance.

7. The optical coupling system of claim 5, wherein the first cut and the second cut are made on each of the micro-ellipsoid lenses after bonding.

8. The optical coupling system of claim 1, wherein only one of the Tx optical signals and the Rx optical signals are transported.

9. The optical coupling system of claim 1, wherein the micro-ellipsoid lenses have near ellipsoid shapes.

10. The optical coupling system of claim 1, further comprising:
a modulator for the Tx optical signals or demodulator for the Rx optical signals;
a multiplexer for the Tx optical signals or de-multiplexer for the Rx optical signals; and
a bridge for the Tx optical signals or de-bridge for the Rx optical signals.

11. An optical coupler, comprising:
a fiber holder part holding an array of optical fibers;
a lens part comprising an array of the micro-ellipsoid lenses, wherein each micro-ellipsoid lens having an ellipsoid shape and comprising a first focus and a second focus, and wherein each micro-ellipsoid lens comprises a first cut near or at the first focus and a second cut near or at second focus;
a PCB board comprising at least one of a vertical cavity surface emitting lasers (VCSEL) and a photodiode (PD), said VCSEL emits transmission (Tx) optical signals and said PD receives reception (Rx) optical signals, said silicon photonics chip is placed near the first focus;
where in the array of optical fibers is placed near the second focus;
wherein the Tx optical signals are emitted from the VCSEL and received by the optical fiber array, and
wherein the Rx optical signals are emitted from the optical fiber array and received by at least one PD.

12. The optical coupler of claim 11, wherein the Rx and Tx optical signals are totally reflected at a spot on a boundary of the micro-ellipsoid lens.

13. The optical coupler of claim 12, wherein the boundary of the micro-ellipsoid lens is an intact portion of the micro-ellipsoid lens.

14. The optical coupler of claim 11, wherein the Tx optical signal matches the mode of the optical fiber, and the Rx optical signal matches the mode of the PD.

15. The optical coupler of claim 11, where in the array of the micro-ellipsoid lens of comprising:
a plurality of the micro-ellipsoid lens made from preliminary micro-ellipsoid lens which each preliminary micro-ellipsoid lens is cut on a first side and a second side;
wherein the first side and the second side are identical and are located on opposing sides of the micro-ellipsoid lens; and
wherein the cut plurality of the micro-ellipsoid lenses is bonded to each other on the first sides and the second sides to form the array.

16. The optical coupler of claim 15, wherein the plurality of micro-ellipsoid lenses are aligned using parallel light to ensure at least one of a focal area tolerance, pitch tolerance and spot size tolerance.

17. The optical coupler of claim 15, wherein the first cut and the second cut are made on each of the micro-ellipsoid lenses after bonding.

18. The optical coupler of claim 11, wherein only one of the Tx optical signals and the Rx optical signals are transported.

19. The optical coupler of claim 11, wherein the micro-ellipsoid lenses have near ellipsoid shapes.

20. The optical coupler of claim 11, further comprising:
a modulator for the Tx optical signals or demodulator for the Rx optical signals;
a multiplexer for the Tx optical signals or de-multiplexer for the Rx optical signals; and
a bridge for the Tx optical signals or de-bridge for the Rx optical signals.
